(19) United States
(12) Patent Application Publication
(10) Pub. No.: US 2003/0102223 A1
(43) Pub. Date: Jun. 5, 2003

(54) Method of copper plating via holes

(76) Inventors: Toshihisa Shimo, Kariya-shi (JP); Toshiki Inoue, Kariya-shi (JP); Kyoko Kumagai, Kariya-shi (JP); Yoshifumi Kato, Kariya-shi (JP); Takashi Yoshida, Kariya-shi (JP); Masanobu Hidaka, Kariya-shi (JP)

Correspondence Address: MORGAN & FINNEGAN, L.L.P., 345 Park Avenue, New York, NY, 10154, US

(21) Appl. No.: 10/213,644

(22) Filed: Aug. 7, 2002

(30) Foreign Application Priority Data
Aug. 8, 2001 (JP) 2001-240276

(51) Int. Cl. B05D 5/12; C25D 5/18; H05K 3/00

(52) U.S. Cl. 205/125; 427/97; 205/104

(57) ABSTRACT

A copper plating method for a via hole formed on a multi-layer substrate is provided. The via hole interconnects conductive layers of the multi-layer substrate. The method includes performing chemical copper plating on an inner wall of the via hole and performing electrolytic copper plating on the inner wall of the via hole, on which the chemical copper plating has been performed. The electrolytic copper plating includes a first stage and second stage. The first stage is performed with a current density equal to or less than 1.5 A/dm² to deposit copper film having a thickness of 1 μm or more. The second stage is performed at a current density higher than that in the first stage.

### BACKGROUND OF THE INVENTION

The present invention relates to a copper plating method, and more particularly, to a method for copper plating via holes for interconnecting wiring layers (conductor layers) in a multi-layer substrate.

To increase the density of a multi-layer wiring board (multi-layer substrate), build-up wiring boards are used. The build-up wiring board employs via holes for interconnecting wiring layers. If the via holes are used only for interconnecting two layers, the inner wall of the via holes need not be plated. However, when three or more layers must be interconnected, via holes 31 not filled with plated metal must be displaced as shown in FIG. 4(a). On the other hand, via holes 31 filled with plated metal 32 can be stacked as shown in FIG. 4(b), allowing a higher degree of freedom in the layout of wires.

Conventional via holes have diameters of approximately 100 μm, so that via holes not plated inside do not impede the conductance between each of the layers. However, as via holes have smaller diameters, via holes not plated inside cause an increase in resistance to impede the conductance between each of the layers.

To connect layers with fill-plated via holes, a smear removing process and a catalyst applying process are performed after via holes are formed in a resin insulation layer. Thereafter, a chemical copper plating layers are formed on the bottom and the inner wall of the via holes. Then, fill-plating layer is formed in the via holes through electrolytic copper plating.

To further increase the density of multi-layer substrate, decreasing the diameter of via holes below 70 μm is under consideration. Specifically, decreasing the diameter of via holes to 40 μm or 20 μm is under consideration.

In a conventional electrolytic copper plating method, electrolytic copper plating needs to be performed for an extended period at a low current density (for example, 100 minutes at 1 A/dm²) to maintain the reliability of the fill plated via holes above a predetermined standard. The conventional method therefore has low productivity. If the current density is simply increased to complete the fill plating of via holes in a short time, most of the via holes do not satisfy a thermal shock test, which is one item of a via hole reliability test. The thermal shock test involves 1000 repetitions of immersion in a liquid at −55° C. and in a liquid at 125° C. each for three minutes, and a resistance changing percentage within ±10% is determined as passed.

### SUMMARY OF THE INVENTION

It is an objective of the present invention to provide a method of copper plating via holes, which method completes fill plating via holes with sufficiently reliability in a short time even if the diameter of the via holes is 40 μm.

To achieve the foregoing and other objectives and in accordance with the purpose of the present invention, a copper plating method for a via hole formed on a multi-layer substrate is provided. The via hole interconnects conductive layers of the multi-layer substrate. The method includes: performing chemical copper plating on an inner wall of the via hole; performing electrolytic copper plating on the inner wall of the via hole, on which the chemical copper plating has been performed, wherein the electrolytic copper plating includes a first stage and second stage, wherein the first stage is performed with a current density equal to or less than 1.5 A/dm² to deposit copper film having a thickness of 1 μm or more, wherein the second stage is performed at a current density higher than that in the first stage.

The present invention also provides another a copper plating method for a via hole formed on a multi-layer substrate. The via hole interconnects conductive layers of the multi-layer substrate. The method includes: performing chemical copper plating on an inner wall of the via hole; performing electrolytic copper plating on the inner wall of the via hole, on which the chemical copper plating has been performed, wherein the electrolytic copper plating includes a first stage and second stage, wherein the first stage is performed with a low current density, wherein the second stage is performed at a current density higher than that in the first stage plating, wherein, in each stage, positive pulses and negative pulses are alternately supplied, and wherein the conduction amount of the positive pulses is greater than that of the negative pulses.

Other aspects and advantages of the invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIGS. 1(a) to 1(d) are schematic cross-sectional views showing a procedure of forming a fill-plating layer of a via hole according to one embodiment of the present invention;

FIG. 2(a) is a time chart showing plating conditions in the procedure of FIGS. 1(a) to 1(c);

FIG. 2(b) is a schematic time chart showing pulse plating conditions in the procedure of FIGS. 1(a) to 1(c);

FIG. 3(a) is a schematic cross-sectional view of a substrate for reliability evaluation in the procedure of FIGS. 1(a) to 1(c);

FIG. 3(b) is a schematic cross-sectional view of a via hole for explaining the filling factor of the via hole;

FIG. 4(a) is a schematic cross-sectional view when via holes are not fill-plated; and

FIG. 4(b) is a schematic cross-sectional view when prior art via holes are fill-plated.

### DETAILED DESCRIPTION OF THE PREFERRED EMBODIMENTS

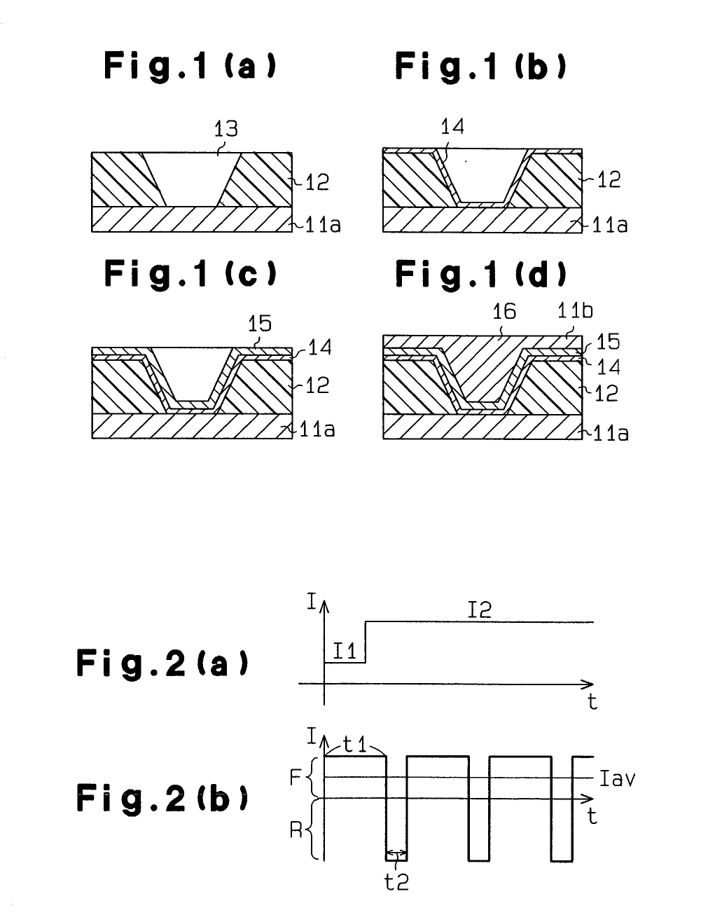

An embodiment of a method of forming via holes according to the present invention will be described below with reference to FIGS. 1(a) to 3(b). In this embodiment, via holes having a diameter of 40 μm are formed.

For forming fill-plated via holes for electrically interconnecting conductive layers formed on upper and lower sides of a multi-layer substrate, an insulating layer 12 is first formed on an underlying conductive layer 11a, and then a via hole 13 is formed by irradiation of laser, as shown in FIG. 1(a). Next, a smear removing process is performed. Thereafter, the catalyst applying step and chemical copper plating step are performed on the inner wall of the via hole 13 and an upper layer on which a conductive layer 11b is to be formed to form a thin chemical copper plating layer 14, as shown in FIG. 1(b).

Next, the electrolytic copper plating step is performed. The electrolytic copper plating step is performed in two stages. As shown in FIG. 2(a), in the first stage, electrolytic copper plating is performed for a predetermined time period at a low current density, and in the second stage, plating is performed at a high current density. The first stage plating forms a dense electrolytic copper plating layer 15 in a predetermined thickness on the chemical copper plating layer 14 as shown in FIG. 1(c). Then, the second stage plating forms a fill plating layer 16 to fill a remaining portion of the via hole 13 to form the electrolytic copper plating layer 15. In FIGS. 1(c) and 1(d), the chemical copper plating layer 14, the electrolytic copper plating layer 15, and the fill plating layer 16 are illustrated in a distinctive manner. However, in reality, the interfaces of the layers are not as distinctive as illustrated.

The electrolytic copper plating is performed with the current density within an allowable current range of a plating bath. The first stage plating is performed with the current density equal to or less than 1.5 A/dm² to deposit copper in a thickness of 1 μm or more, preferably in a range of 1.5 to 2.0 μm. Then, the second stage plating is performed at a current density higher than that in the first stage plating. Though depending on the composition of the plating bath of the electrolytic copper plating, the current density in the second stage plating is preferably on the order of 3 A/dm² to complete the electrolytic copper plating for approximately 30 minutes in total.

FIG. 2(a) is a graph showing the relationship between the current value (I) and the time (t) in the electrolytic copper plating. FIG. 2(b) is a graph schematically showing changes in the supplied current value in a pulse plating. The timescale of FIG. 2(a) is different from that of FIG. 2(b).

As shown in FIG. 2(b), the electrolytic copper plating is performed with pulse plating, which includes alternating positive pulses and negative pulses, with a larger conduction amount set for the positive pulses. The ratio t1/t2, a conduction time t1 of the positive pulses to a conduction time t2 of the negative pulses, of the pulse plating is set to a ratio between 5/1 to 30/1. Preferably, the ratio t1/t2 is set at a ratio between 8/1 to 20/1. The conduction time t1 is each set to approximately 40 to 60 ms. Setting each conduction time t1 short causes pulse to be switched too frequently and is therefore undesirable. Setting each conduction time t1 lower than a predetermined period degrades the quality of the plating layer and is therefore undesirable.

The ratio F/R, a current value F of the positive pulses to a current value R of the negative pulses, of the pulse plating is set at a ratio between 1/2 to 1/5.

The present invention will be described below in greater detail in connection with examples and comparative examples.

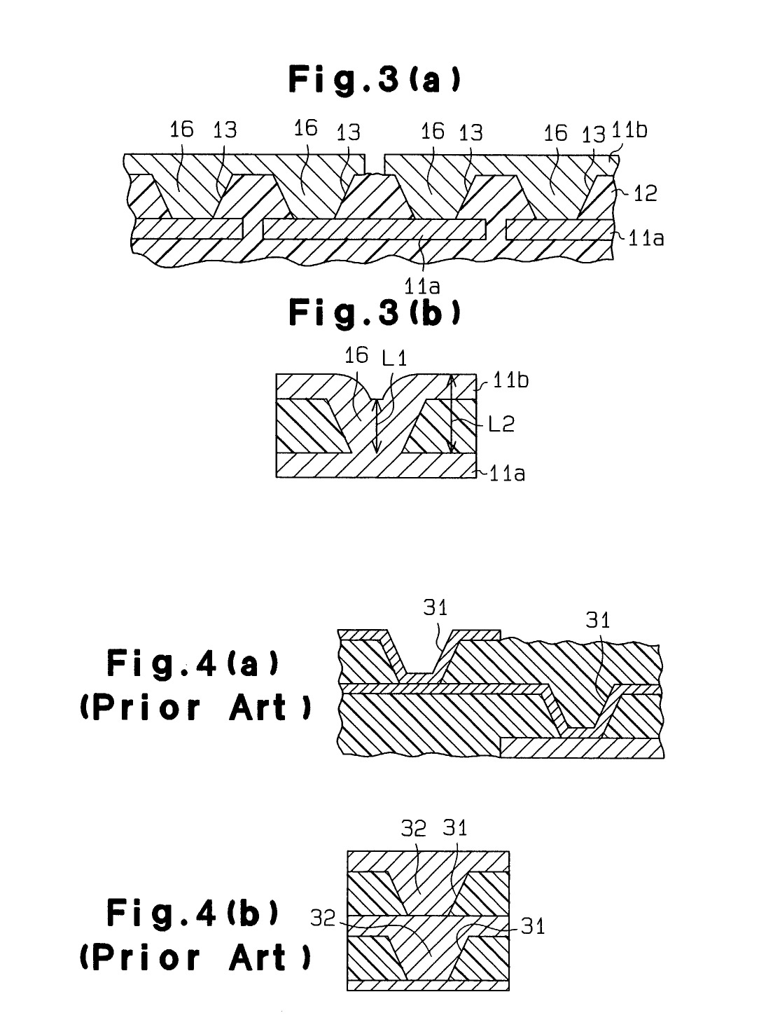

First, an evaluation substrate formed with a large number of via holes 13 as shown in FIG. 3(a). Then, a fill plating of the via holes 13 is performed after changing the plating conditions. In the examples and the comparative examples, the smear removing process, the catalyst applying step and chemical copper plating step were performed under known processing conditions. Used as additives to a plating bath in the electrolytic copper plating were Impulse H (trade name) brightener and leveler manufactured by Atotech. Respective doses were chosen to be 2.5 ml/l of brightener, and 8 ml/l of leveler, as recommended by the manufacturer.

Then, the resulting samples the filling factor of which is equal to or more than 90% underwent a reliability evaluation, which consisted of four items shown in Table 1, i.e., a high temperature standing test, a high temperature/high humidity standing test, a thermal shock test, and a soldering heat test.

The filing factor is expressed by an equation filling factor=(L1/L2)×100(%), in which L1 is the distance between the upper surface of the conductive layer 11a and the upper surface of the fill plating layer 16 of the via holes 13, and L2 is the distance between the conductive layer 11a and the upper surface of the conductive layer 11b.

TABLE 1

| | | Evaluation |
|---|---|---|
| Item | Condition | criteria |
| High temperature | 150° C. × 1000 hours | Resistivity |
| standing test | | changing |
| High | 85° C., 85% RH × | percentage |
| temperature/high | 1000 hours | within ±10% |
| humidity | | |
| standing test | | |
| Thermal shock | −55° C., 125° C. (three | |
| test | minutes each) × | |
| | 1000 cycles | |
| Solder heat test | 280-290° C. × 30 seconds | |

In the soldering heat test, samples were immersed in a soldering bath at 280 to 290° C. for a predetermined time period, for example, 30 seconds, and cooled down, and the resistances were measured.

Within the four items of the evaluation test, the comparative examples also passed the high temperature standing test, the high temperature/high humidity standing test, and the soldering heat test. However, the comparative examples presented a low successful rate in thermal shock test. After the thermal shock test, via holes of the examples were observed through a scanning electron microscope. The observation discovered voids and deposition of dendrite in the fill plating layers of the examples that presented a low successful rate in the reliability.

Table 2 shows the plating conditions and the pass rate in the thermal shock test of the examples and the comparative examples.

TABLE 2

| | | | | | | | Reliability |
|---|---|---|---|---|---|---|---|
| | t1/t2 | | | | T1 | T2 | Pass Rate |
| | (ms/ms) | F/R | A1* | A2* | (min) | (min) | (%) |
| Example 1 | 40/2 | 1/3 | 1 | 3 | 10 | 20 | 100 |
| Example 2 | 40/2 | 1/3 | 1.5 | 3 | 8 | 20 | 100 |
| Example 3 | 40/5 | 1/3 | 1 | 3 | 10 | 20 | 100 |
| Example 4 | 60/2 | 1/3 | 1 | 3 | 10 | 20 | 100 |
| Example 5 | 40/2 | 1/3 | 1 | 3 | 7 | 21 | 100 |
| Example 6 | 40/2 | 1/5 | 1 | 3 | 10 | 20 | 100 |
| Example 7 | 40/2 | 1/2 | 1 | 3 | 10 | 20 | 100 |
| Example 8 | 40/8 | 1/2 | 1 | 3 | 10 | 20 | 100 |
| Comparative | 40/2 | 1/3 | 1 | — | 100 | — | 100 |
| Example 1 | | | | | | | |
| Comparative | DC | DC | 1 | 3 | 10 | 45 | 45 |
| Example 2 | | | | | | | |
| Comparative | 40/2 | 1/3 | — | 3 | — | 25 | 30 |
| Example 3 | | | | | | | |

*A/dm²
T1: Plating Time in Low Current Density
T2: Plating Time in High Current Density

Referring to the comparative example 1 in table 2, an electrolytic plating at a low current density (1 A/dm²) for a long period (100 minutes) formed a fill plating layer having a sufficient reliability. However, the time for the comparative example 1 took was excessively long. Referring to the comparative example 2, performing fill plating of via holes in two stages with direct current (a low current density stage and a high current density stage) shortened the plating time. However, the reliability was not sufficient. Referring to the comparative example 3, a fill plating only with a high current density resulted in an insufficient reliability.

In the examples 1 to 8, fill plating layers having 100% of reliability were obtained in 30 minutes of plating time. Particularly, observation of the cross-section of the via holes discovered that the example 1 has the best quality in the plating layer.

The illustrated embodiment has the following advantages.

(1) When fill plating the inside the via holes 13, which connects the upper and lower conductive layers of the multi-layer substrate, the fill plating is performed with the current density of 1.5 A/dm², which is in the allowable current range of the plating bath, to deposit film in a thickness of 1 μm or more. Then, the rest of the plating is performed at a current density higher than that 1.5 A/dm². Thus, deposition of dendrite crystals is prevented and copper is electrolytically plated densely and uniformly on the surface of the chemical copper plating layer 14. Also, voids, which affect the reliability, do not occur in the via holes, so that the via holes is plated in a short time.

(2) The electrolytic copper plating is performed with pulse plating, which includes alternating positive pulses and negative pulses, with a larger conduction amount set for the positive pulses. Therefore, unlike plating with a direct current of high current density, plating layer is prevented from being formed quickly at the opening of each via hole 13. Thus, the opening of each via hole 13 is not blocked while there is still a space in the via hole 13.

(3) When the electrolytic copper plating is performed, the first stage plating of low current density and the second stage plating of high current density both include alternating positive pulses and negative pulses, with a larger conduction amount set for the positive pulses. Therefore, fill plating layer of sufficient reliability is formed in a short time.

(4) The ratio t1/t2, a conduction time t1 of the positive pulses to a conduction time t2 of the negative pulses, of the pulse plating is set to a ratio between 5/1 to 30/1. Therefore, the plating is performed in a stable manner and the fill plating layer 16 having sufficient reliability is formed.

(5) The ratio F/R, a current value F of the positive pulses to a current value R of the negative pulses, of the pulse plating is set at a ratio between 1/2 to 1/5. Therefore, the plating is performed in a stable manner and the fill plating layer 16 having sufficient reliability is formed.

It should be apparent to those skilled in the art that the present invention may be embodied in many other specific forms without departing from the spirit or scope of the invention. Particularly, it should be understood that the invention may be embodied in the following forms.

In the plating with high current density, the current density need not be constant. The current density may be increased at a constant or discrete rate. For example, to set the average current density in the high current density plating to a predetermined value (for example, 3 A/dm²), the current density may changed from a value that is lower than 3 A/dm² to a value that is higher than 3 A/dm²

The electrolytic copper plating for depositing a thickness of 1 μm or more with a current density equal to or lower than 1.5 A/dm² in an allowable current range of the plating bath may be performed by supplying DC power, rather than pulse plating, and the subsequent electrolytic copper plating with a high current density may be performed using the pulse plating.

The diameter of the via holes 13 is not limited to 40 μm, but the present invention may be applied to via holes having diameters larger than 40 μm or to via holes having diameters of approximately 20 μm which are smaller than 40 μm.

Therefore, the present examples and embodiments are to be considered as illustrative and not restrictive and the invention is not to be limited to the details given herein, but may be modified within the scope and equivalence of the appended claims.

1. A copper plating method for a via hole formed on a multi-layer substrate, the via hole interconnecting conductive layers of the multi-layer substrate, the method including:
performing chemical copper plating on an inner wall of the via hole;
performing electrolytic copper plating on the inner wall of the via hole, on which the chemical copper plating has been performed, wherein the electrolytic copper plating includes a first stage and second stage, wherein the first stage is performed with a current density equal to or less than 1.5 A/dm² to deposit copper film having a thickness of 1 μm or more, wherein the second stage is performed at a current density higher than that in the first stage.

2. The method according to claim 1, wherein at least the second stage is performed with pulse plating, in which positive pulses and negative pulses are alternately supplied, and wherein a conduction amount of the positive pulses is greater than that of the negative pulses.

3. The method according to claim 2, wherein the ratio of the conduction time of the positive pulses to the conduction time of the negative pulses is in a range of 5/1 to 30/1.

4. The method according to claim 2, wherein the ratio of the current value of the positive pulses to the current value of the negative pulses is in a range of 1/2 to 1/5.

5. The method according to claim 1, wherein, in the first stage, positive pulses and negative pulses are alternately supplied, and wherein the conduction amount of the positive pulses is greater than that of the negative pulses.

6. The method according to claim 1, wherein the first stage is performed with the current density substantially of 1 A/dm².

7. The method according to claim 1, wherein the second stage is performed with the current density substantially of 3 A/dm².

8. A copper plating method for a via hole formed on a multi-layer substrate, the via hole interconnecting conductive layers of the multi-layer substrate, the method including:
performing chemical copper plating on an inner wall of the via hole;
performing electrolytic copper plating on the inner wall of the via hole, on which the chemical copper plating has been performed, wherein the electrolytic copper plating includes a first stage and second stage, wherein the first stage is performed with a low current density, wherein the second stage is performed at a current density higher than that in the first stage plating, wherein, in each stage, positive pulses and negative pulses are alternately supplied, and wherein the conduction amount of the positive pulses is greater than that of the negative pulses.

9. The method according to claim 8, wherein the ratio of the conduction time of the positive pulses to the conduction time of the negative pulses is in a range of 5/1 to 30/1.

10. The method according to claim 8, wherein the ratio of the current value of the positive pulses to a current value of the negative pulses is in a range of 1/2 to 1/5.

11. The method according to claim 8, wherein the first stage is performed with a current density equal to or less than 1.5 A/dm².

12. The method according to claim 8, wherein the current density in the second stage is substantially of 3 A/dm².
